(19) United States
(12) Patent Application Publication
(10) Pub. No.: US 2009/0009182 A1
(43) Pub. Date: Jan. 8, 2009

(54) CIRCUIT TO PROVIDE TESTABILITY TO A SELF-TIMED CIRCUIT

(76) Inventors: JOHN BAINBRIDGE, Withington (GB); SEAN SALISBURY, Fallowfield (GB); GEORGE LANDER, Victoria Park (GB)

Correspondence Address: MICHAEL W. CALDWELL, 4226 RIVERMARK PARKWAY, SANTA CLARA, CA, 95054-4150, US

(21) Appl. No.: 11/757,500

(22) Filed: Jun. 4, 2007

(51) Int. Cl. G01R 31/02

(52) U.S. Cl. 324/537

(57) ABSTRACT

The present invention enables asynchronous circuits to be tested in the same manner and using the same equipment and test strategies as with synchronous circuits. The feedback path of an asynchronous element, for example a Muller C element, includes a test structure which may be invoked for the purpose of providing the means for synchronous testing. When configured for testing, the test structure provides a clocked latching and selecting function which, by virtue of breaking the feedback path of the self-timing device, prevents the device being tested from switching states until desired. When the element is not in test mode, the test structure is configured to pass through the data that normally flows through the feedback path unchanged. The result is an ability to test an asynchronous device or subsystem of a device in the same manner as and/or intermixed with a synchronous device.

### BACKGROUND

Asynchronous circuits, often referred to as “clockless circuits” or “self-timed” circuits offer many advantages over synchronous circuits when used in digital logic comprising electronic products, such as integrated circuits. A significant advantage of asynchronous circuits is lower power compared to the same function implemented using synchronous design techniques. Historically, synchronous designs have been more widely used than asynchronous designs, partly due to such factors as smaller die area required and easier and better understood testing capability. Products designed with either methodology must be individually tested after fabrication to ensure proper execution when the product is operated. Test methods, test equipment, and test engineers are more widely available for the testing of products using synchronous design than for testing products designed using asynchronous circuits. Thus it would be beneficial to test an asynchronous product using the same equipment and techniques used in testing a synchronous product, particularly for testing devices embodying logic designed using both synchronous and asynchronous circuits.

A typical method for testing a synchronous device is to clock predetermined data into certain flip flops wherein the flip flops are configured to provide the data to a logical block with which the flip flops are associated. The logical block is clocked, for example one clock cycle, then the flip flops are configured to receive the resulting data from the logical block. Some or all of the flip flops may be configured to be connected in series, such that the predetermined data is sequentially clocked into the flip flops, then the data is clocked into the logical block, after which the results are clocked out of the logical block, then finally the resulting data is clocked out to be examined by a tester. As was the test data to be clocked in predetermined, the data that is expected to be clocked back out of the DUT (“Device Under Test” is predetermined. A tester comprising logic, such as a computer, compares the data clocked out of the device to the predetermined expected data. If the comparison fails, the DUT is deemed flawed and may be discarded.

Inherent in the testing of synchronous circuits is the ability to predictably move data from one point to the next, including the knowledge of when the data will be stabilized and may be reliably evaluated. However asynchronous circuits, for example a Muller C element, include a feedback path which may change state at an unpredictable time, making testing by the method used for synchronous circuits not possible. Therefore what is needed is a design methodology that enables asynchronous circuits to operate as self-timed elements but be tested using the methods of synchronous circuits.

Solutions have been suggested in the literature, for example by Berkel et al (Adding Synchronous and LSSD Modes to Asynchronous Circuits, IEEE 1522-8681/02, p 2), hereinafter “Berkel”. In the solution of Berkel (see FIG. 3) asynchronous circuits are brought outside of the logic block and modified to include latches to provide a scan chain. However the solutions suggested to date result in a significant reduction in performance of the circuit during normal operation.

### SUMMARY

The present invention enables asynchronous circuits to be tested in the same manner and using the same equipment and test strategies as with synchronous circuits. The operational performance of a circuit implemented according to the invention is approximately twenty-five percent improved compared to the previously suggested methods. When designed according to the present invention, the feedback path of an asynchronous element includes a test structure which may be invoked for the purpose of providing the means for synchronous testing. When configured for testing, the test structure provides a clocked latching and selecting function which, by virtue of breaking the feedback path of the clockless device, prevents the clockless device being tested from switching states until desired: when the test structure is clocked. During operation, that is, when the device is not in test mode, the test structure is configured to simply pass through the data that flows through the feedback path unchanged. The result is an ability to test an asynchronous device or subsystem of a device in the same manner as and/or intermixed with a synchronous device.

### BRIEF DESCRIPTION OF THE DRAWINGS

FIG. 1 shows a standard symbol and circuit block diagram for a typical flop flop. PRIOR ART.

FIG. 2 shows a standard symbol and circuit block diagram for a typical flip flop, the flip flop including test structures. PRIOR ART.

FIG. 3 is a block diagram of a typical circuit for testing a logic block using standard synchronous components, including a flip flop from FIG. 2. PRIOR ART.

FIG. 4 shows a standard symbol and circuit block diagram for a Muller C element. PRIOR ART.

FIG. 5 shows a Muller C element, similar to that of FIG. 4, incorporating test structures. PRIOR ART.

FIG. 6 shows a standard symbol and circuit block diagram for an alternative embodiment of a Muller C element. PRIOR ART.

FIG. 7 shows a Muller C element, similar to that of FIG. 6, incorporating test structures according to the present invention.

FIG. 8 is a timing diagram of the signals during a test operation of a Muller C element, wherein the Muller C element includes a test structure according to the present invention.

### DESCRIPTION OF SOME EMBODIMENTS

### Definition of Terms

| | |
|---|---|
| DUT | Device under test (by a tester). |
| Q | Symbol used to signify the output terminal of a logical element, |
| | such as a flip flop, an AND gate, a Muller C element, and the like. |

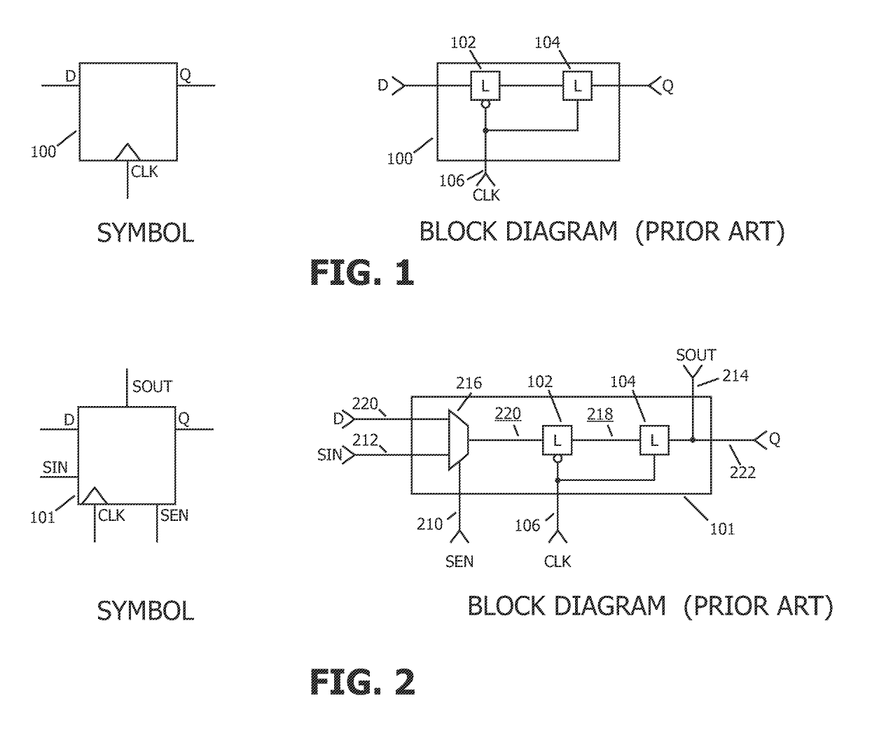

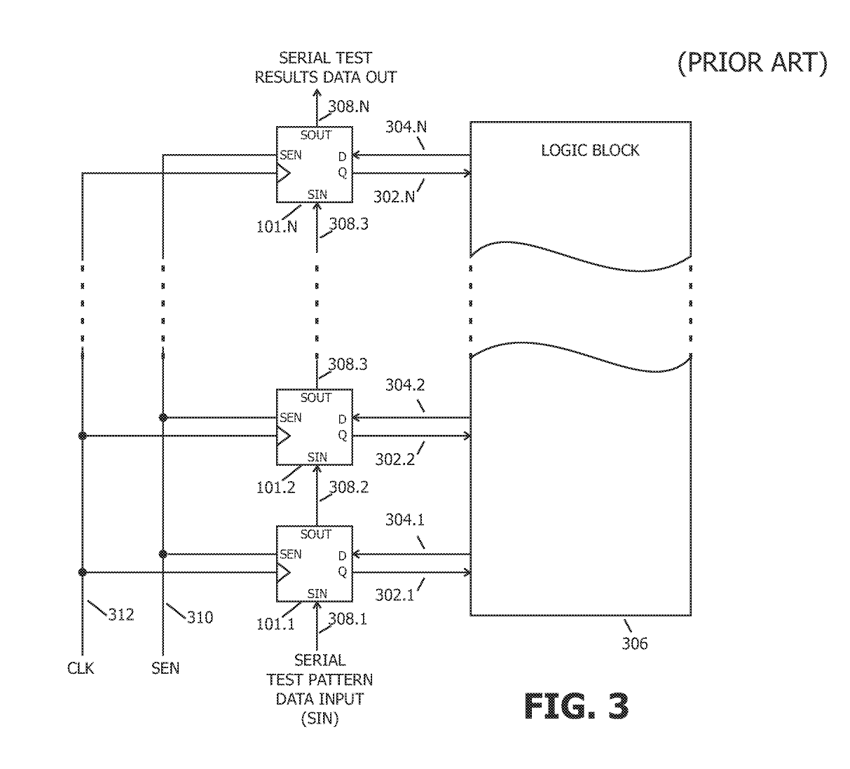

FIG. 1 shows a block diagram of a typical design for a flip flop 100. As is well known, a signal D is clocked successively through a first latch 102 on a negative CLK signal on line 106, and is clocked out as signal Q through a second latch 104 during a positive CLK signal. FIG. 2 shows how a flip flop, for example flip flop 100, may be modified to form a flip flop 101, wherein the structures added to flip flop 100 enable flip flop 101 to operate as a “regular” flip flop, such as flip flop 100, or be reconfigured to perform testing functions. Flip flop 101 is formed from flip flop 100 by adding a MUX 216, wherein MUX 216 may be configured to select between the input signal D on line 220 or an input signal SIN on line 212, the selection responsive to the selection signal SEN on line 210. The selected input is passed directly to a first latch 102 on line 220 and is latched in by a negative CLK signal on line 106, later clocked out of the second latch 104 as the signal Q by a positive signal CLK on line 106. Thus, as may be seen from FIG. 2, when the MUX 216 is configured to select signal D on line 220, flip flop 101 behaves exactly as flip flop 100. When the MUX 216 is configured to select signal SIN on line 212, the operation of flip flop 101 is still the same as that of flip flop 100, except that the signal SIN is clocked through the flip flop instead of the signal D. A signal SOUT on line 214 is available as a copy of the output signal Q, wherein line 214 may be electrically connected to an electrical connection that is not the same as the electrical connection of line 222.

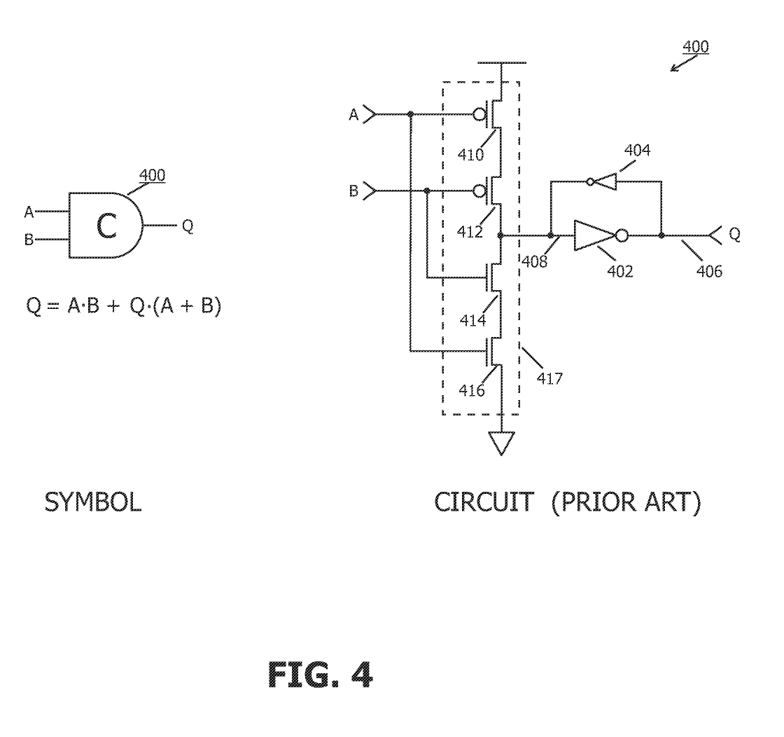

For example, looking to FIG. 3, one or more flip flops (101.1 through 101.N, sometimes referred to collectively as simply “flip flops 101”) are connected to a logic block to be tested, for example the block referenced as 306, by their respective D and Q lines (304.1 through 304.N and 302.1 through 302.N, respectively). The D and Q connections are the normal (that is, for normal operation of the logic block 306) connections to the logic block 306. The D and Q terminals of a given flip flop may also have other electrical connections, not shown for simplicity, for the purpose of providing the logical behaviors and interconnections of the integrated circuit within which the flip flops are instantiated. When the signal SEN on line 310, connected in common to the flip flops, is FALSE, the N flip flops 101 operate normally. When the signal SEN to the flip flops 101 on line 310 is TRUE, the SIN terminal of each flip flop is electrically connected through the internal latches and MUX to the SOUT of a preceding flip flop (as may be understood by referring to FIG. 3 and FIG. 2). Serial data SIN, referred to as a “test pattern” by test engineers, is shifted into the first flip flop 101.1, on line 308.1, when clocked by signal CLK on line 312. Line 312 is in common to all of the associated flip flops 101 clock input terminals. As clock signal CLK on line 312 is toggled, the test pattern data is shifted from a given flip flop's input terminal SIN to the given flip flop's SOUT output. CLK continues to be toggled until each of the associated flip flops 101 has latched in its respective test pattern data bit. The signal SEN on line 310 is then deasserted, reconfiguring the flip flops 101 as for normal operation. Then by the next edge of the signal CLK on line 310 the results from logic block 306 have propagated to the D input terminals and are captured in the flip-flop. The signal SEN on line 312 is again asserted and the signal CLK on line 310 is toggled until all of the D data received by the flip flops 101 from the logic block 306 has been shifted out as results data on line 308.N.

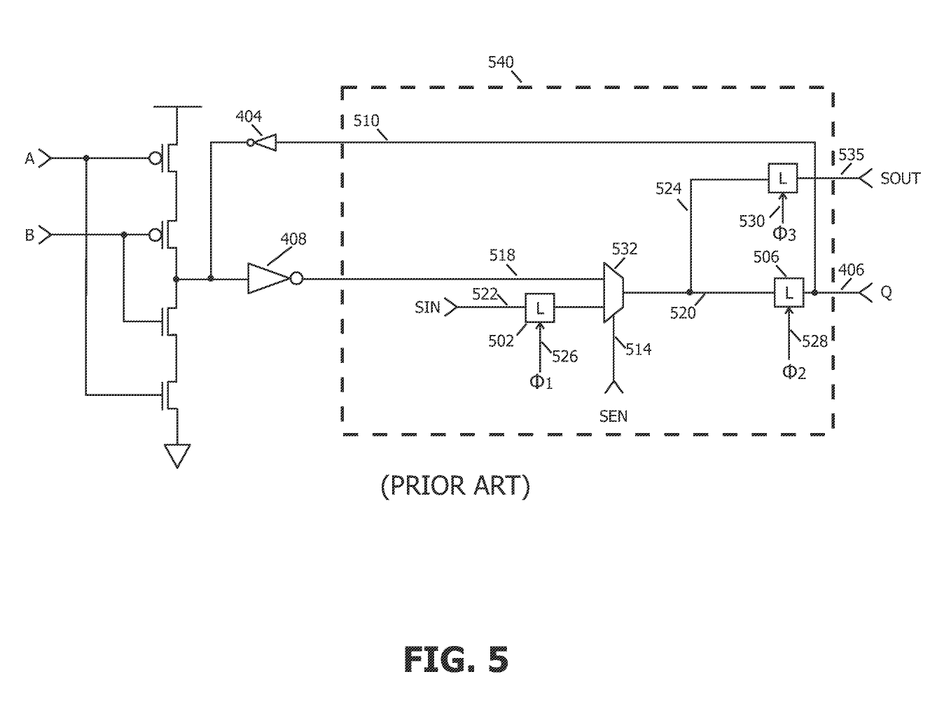

FIG. 4 shows a typical self-timed circuit element, a “Muller C element” 400. Examining the circuit diagram, the input signals A and B at their respective input terminals drive a change in state of the output signal Q on line 406, per the logical expression:

Q=A·B+Q·(A+B). [1]

The expression [1] may be verbally described by the statement that the output signal Q does not change state unless both signals A and B change to the same state. The signal Q on line 406 corresponds to the output of the stacked FETs 417 on line 408, buffered and inverted by the inverter 204. To preserve the output state of signal Q on line 406 as signals A and B change (but not such that signal Q changes), a weak feedback inverter 404 is connected across the inverter 402. The feedback inverter 404 may also diminish or eliminate any glitches on line 406. One skilled in the art will know of other circuits for preserving the state of signal Q on line 406.

The FET stack 417 embodies the term (A·B) of expression [1]. For example, if A=B=1, FETs 410 and 412 will be driven off, and FETs 414 and 416 will be driven on, thus the input terminal to inverter 402, connected to a ground signal on line 408, will be pulled down and the output of the inverter 402 will drive high, providing the FET stack 417 output on line 408 is stronger than the weak feedback inverter 404. Similarly, if A=B=0, FETs 410 and 412 will be driven on, and FETs 414 and 416 will be driven off, thus the input terminal to inverter 402, connected to a high voltage signal on line 408, will be pulled up and the output of the inverter 402 will drive low, again providing the FET stack 417 output on line 408 is stronger than the weak feedback inverter 404. Thus the condition of A=B=1 corresponds to a SET of the cell 400 and the condition of A=B=0 corresponds to a RESET of the cell 400. Any other condition causes no change in the cell 400. For example, if A=1 and B=0, the output of the FET stack 417 will float and the weak feedback inverter 404 will prevent the input signal on line 408 from changing, therefore the inverter 402 output (and Q) do not change. This condition, i.e., preservation of the signal Q when signals A and B are different, embodies the term Q·(A+B) of expression [1].

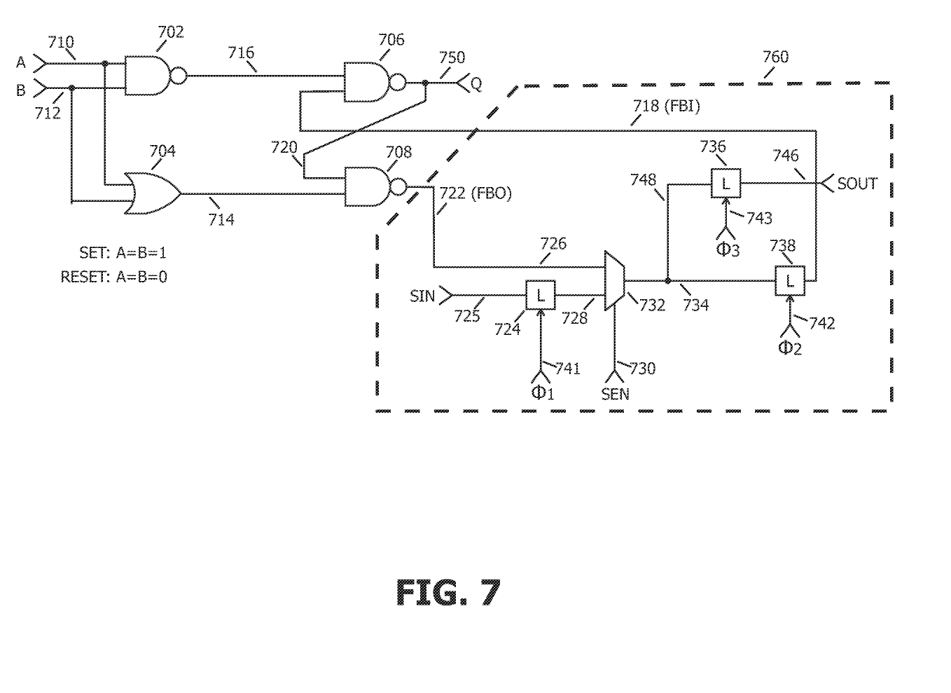

FIG. 6 is another embodiment of a Muller C element 600. Note that the Muller C element 600 is logically equivalent to the Muller C element 400 in FIG. 4. The behavior of the cell 600 is described by Table 1. The table entries correspond to the input signals A and B, followed by the output of the logic gates corresponding to the reference numbers in FIG. 6. “X” indicates that the output of a gate is in determinant; that is, no change from the previous output signal.

TABLE 1

| A | B | 602 | 604 | 606 | 608 (Q) |
|---|---|---|---|---|---|
| 0 | 0 | 1 | 0 | 1 | 0 |
| 0 | 1 | 1 | 1 | X | X |
| 1 | 0 | 1 | 1 | X | X |
| 1 | 1 | 0 | 1 | 0 | 1 |

The Muller C elements of FIG. 4 and FIG. 6, then, may be seen to change state of the output signal Q in response to the states of the signals A and B at whatever time signals A and B become equal. When that occurs is not important. That is, the signals A and B do not have to be provided to the cell inputs at any particular time for the output signal Q to respond. Thus by using various versions of self-timed cells, which may have various numbers of input terms, and by providing a cell's output signal Q as an input signal to another self-timed element, one may design a logic block that will evaluate to the correct output state for a given state of inputs independent of any predetermined timing clock signal because each component does not change state until its inputs are valid.

Several advantages may be seen in this arrangement For example, the digital design will automatically respond to changes in temperature or voltage, enabling one to design the logic without regard to worst-case propagation delays that would be necessary in a synchronous, clocked design to insure all terms will be valid by the expiration of the clocking period. However, the lack of deterministic timing of self-timed components, for example the Muller C element of FIG. 4 or FIG. 6, prevents one from using the standard (i.e., synchronous) test method previously discussed in conjunction with FIG. 3.

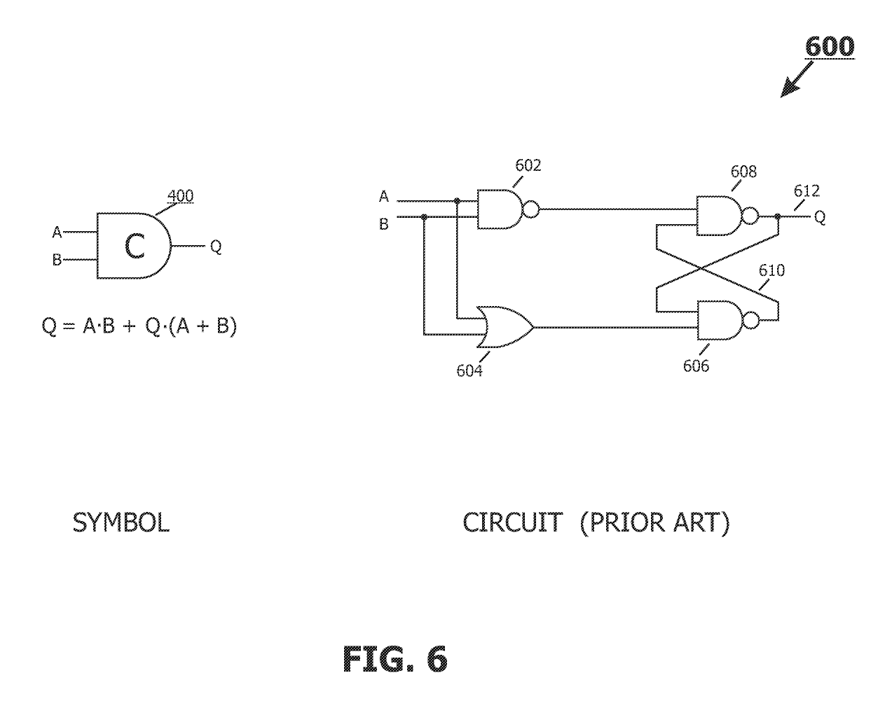

FIG. 5 illustrates a suggested method for providing scan path logic 540 to a Muller C element. The signal SEN on line 514 selects the serial test pattern data SIN on line 522 to be latched through to SOUT on line 535 by the proper application of the three phase clock signals. However, note that during normal operation both rising and falling electronic signals on lie 518 are penalized (increased latency) by the propagation through the MUX 532 and the latch 506.

In accordance with the method of the present invention the circuit of FIG. 6 is modified with scan logic to enable shifting in test pattern data, receiving the results, and shifting the results out to a tester. In one embodiment scan logic is added in series with line 612. Although some performance is given up, as described in connection with FIG. 5, the rising and falling signals would have approximately the same performance characteristics, which is important in some target systems.

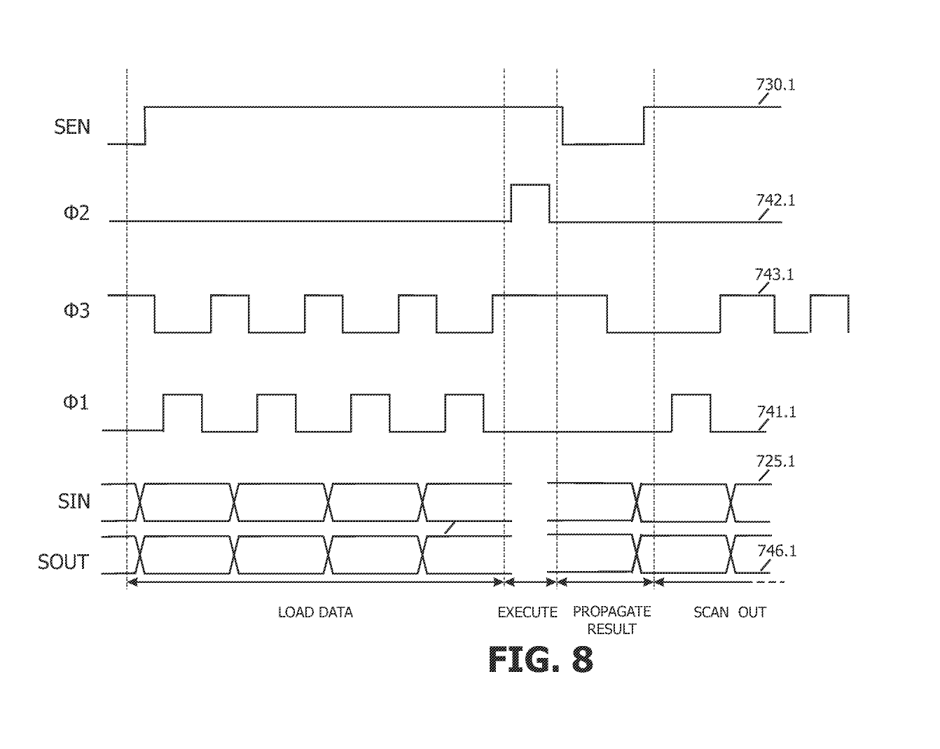

In another embodiment the invention is implemented as shown in FIG. 7, wherein the scan logic 760 is in series with the line 610 of FIG. 6. Looking to FIG. 7, a modified Muller C element is formed by the addition of a MUX 732, a latch 724, a latch 738, and a latch 736 electrically connected as shown, to the Muller C the cell 600 of FIG. 6. A three phase clock, comprising φ1 (“PH1”) on line 741, φ2 (“PH1”) on line 742, and φ3 (“PH3” on line 743, controls the flow of input signal SIN on line 725 to the output signal SOUT on line 746. The clock signal PH1 to latch 724 clocks in the signal SIN to MUX 732, wherein MUX 732 is configured by signal SEN on line 730 to select and receive the output of latch 724 for transfer to line 734 and line 748. Clock PH2 to the latch 742 is held low during this time. Clock PH1 is driven low and clock PH3 is driven high, thus providing a version of the signal SIN, which has been held on lines 734 and 748, to the signal SOUT on line 746. Referring to FIG. 3 and FIG. 9, flip flops 101 may be replaced with the scan logic 760 wherein, as described previously in connection with figures FIG. 2 and FIG. 3, a test pattern may be serially shifted into the Muller C elements of the logic block 912 by electrically connecting the output signal SOUT of each scan logic block (shown as 760.0 through 760.N in FIG. 9) to the input terminal representing SIN of a succeeding cell. The test pattern data is shifted by alternatingly toggling the clocks PH1 and PH3 while signal SEN on line 730 is held high (and PH2 is held low). That is, the serial test pattern data is shifted into the cell 600 on the rising edge of PH1, held between the latches 724 and 736 on the falling edge of PH1, then shifted out of the cell 600 (as SOUT on line 746) on the rising edge of PH3, electrically connected to SIN of the next cell in line. When PH3 goes low, a version of SOUT is trapped between the latch 736 of a given cell and the latch 724 of the next cell in sequence. When PH1 again clocks high, the version of SOUT from the preceding cell is clocked through the MUX 732 until PH1 goes low again. This sequence is repeated until the test pattern has been shifted as required. Note that in FIG. 9 each clock phase is provided to each scan logic block 760 in parallel (connections not shown for clarity).

After the complete test pattern data has been shifted in (that is, a pattern comprising the same number of bits as there are cells 600 in series in a given logic block 912) phase clock PH3 is left in the high state and PH1 in the low state. PH2 is driven high with SEN still set to 1 so that the data forced into the loop via PH2 comes from the scan path (value shifted in previously). PH2 is then driven low to hold this value and allow it to propagate through the feedback path and NAND 706. SEN is driven low to allow any resulting state change on FBO to propagate through latch 736, due to PH3 still driven high, to SOUT. PH3 is driven low to hold the resulting value at SOUT before SEN is driven high allowing the scan out sequence to begin. The scan out sequence is exactly the same as scan in sequence previously described.

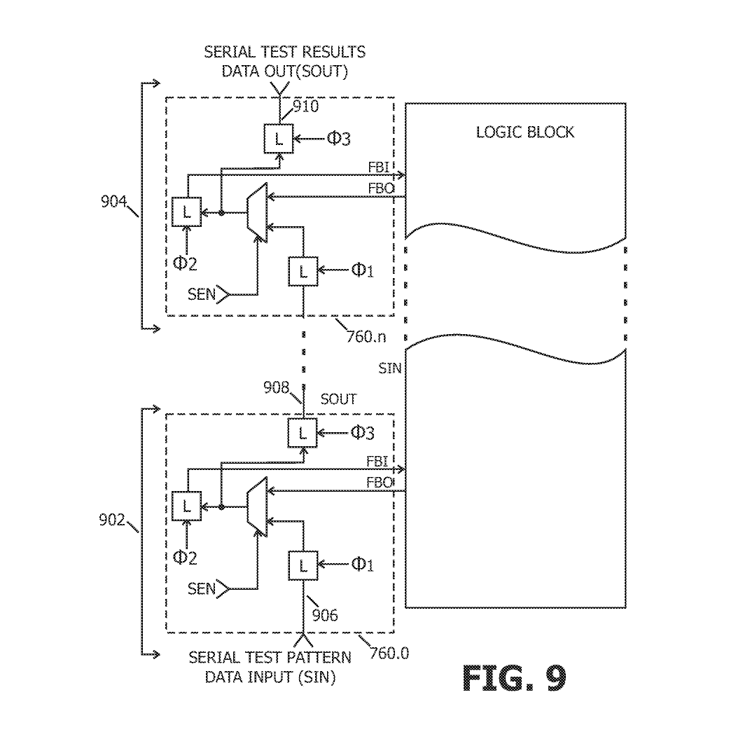

The relationship between the three clock phases, SIN, SOUT and SEN may be understood by referring to FIG. 8. The signals are given reference numerals similar to the line numbers carrying each respective signal, with the addition of The toggling data signal SIN is in sync with the toggling SOUT data signals, but shifted by a number of clock periods corresponding to the number of bits in the test pattern. That is, if the test pattern is, for example, four bits, as the fourth bit of a new test pattern is shifted in, the fourth bit of the results of the previous pattern is shifted out to the tester.

Looking again to FIG. 7, we see that during normal operation of the Muller C element, a SET signal (A=B=1) propagates through NAND gate 702 and is carried to NAND gate 706 by line 716, then the NAND gate 706 output is carried by line 750 to output terminal Q as it would whether or not scan logic 760 were included in the Muller C element. That is, the scan logic 760 is transparent to a SET signal. A RESET signal (A=B=0) propagates through the OR gate 704 on line 714 to NAND gate 708, and is then carried to the MUX 732 on line 726, from the MUX 732 to the latch 738 on line 734, though the latch 738 (clock PH2 being held high on line 742), finally carried to an input terminal of NAND 706 on line 718. Thus a RESET signal is impacted (increased latency) by the propagation delays of the MUX 732 and latch 742 compared to a Muller C element in which no scan logic 760 is implemented. Since only the RESET signals are so effected, the degradation in performance of the system at large will be half the degradation of performance compared to an implementation wherein both signals, SET and RESET, are effected, as was discussed in connection with FIG. 5.

### Reservation of Extra-Patent Rights, Resolution of Conflicts, and and Interpretation of Terms

After this disclosure is lawfully published, the owner of the present patent application has no objection to the reproduction by others of textual and graphic materials contained herein provided such reproduction is for the limited purpose of understanding the present disclosure of invention and of thereby promoting the useful arts and sciences. The owner does not however disclaim any other rights that may be lawfully associated with the disclosed materials, including but not limited to, copyrights in any computer program listings or art works or other works provided herein, and to trademark or trade dress rights that may be associated with coined terms or art works provided herein and to other otherwise-protectable subject matter included herein or otherwise derivable herefrom.

Unless expressly stated otherwise herein, ordinary terms have their corresponding ordinary meanings within the respective contexts of their presentations, and ordinary terms of art have their corresponding regular meanings

We claim:

1. A circuit to enable synchronous testing of a one or more asynchronous circuit element, wherein the one or more asynchronous circuit elements include a one or more feedback path, comprising:
a circuit for interrupting at least one of the one or more feedback paths;
means for synchronously shifting at least one data bit into the interrupting circuit; and
means for synchronously shifting at least one data bit out of the interrupting circuit.

2. A circuit to enable synchronous testing of a one or more asynchronous circuit element, wherein the one or more asynchronous circuit elements include two feedback paths, comprising:
a circuit for interrupting one of the two feedback paths;
means for synchronously shifting at least one data bit into the interrupting circuit; and
means for synchronously shifting at least one data bit out of the interrupting circuit.
